(19) United States
(12) Patent Application Publication
(10) Pub. No.: US 2021/0074655 A1
(43) Pub. Date: Mar. 11, 2021

(54) SECURED FLOATING GATE TRANSISTOR AND METHOD FOR SECURING FLOATING GATE TRANSISTORS

(71) Applicant: University of Louisiana at Lafayette, Lafayette, LA (US)

(72) Inventors: Hossein Zandipour, Lafayette, LA (US); Mohammad R. Madani, Lafayette, LA (US)

(21) Appl. No.: 17/011,190

(22) Filed: Sep. 3, 2020

Related U.S. Application Data
(60) Provisional application No. 62/897,635, filed on Sep. 9, 2019.

(51) Int. Cl. H01L 23/00; H01L 29/788; H01L 21/265; H01L 29/66

(52) U.S. Cl. CPC H01L 23/573; H01L 29/66825; H01L 21/26513; H01L 29/788

(57) ABSTRACT

A system and method for adding security to floating gate transistors (FGT), including applications for guarding integrated circuit (IC) chips against reverse engineering techniques, such as Scanning Capacitance Microscopy (SCM). By adding a processing step to the conventional FGT through adding an oppositely doped implanted layer to the substrate, the FGT state cannot be easily detected with SCM reverse engineering.

### CROSS REFERENCE TO RELATED APPLICATIONS

This application claims priority to U.S. Provisional Application No. 62/897,635, titled SECURED FLOATING GATE TRANSISTOR AND METHOD FOR SECURING FLOATING GATE TRANSISTORS, filed on Sep. 9, 2019.

### STATEMENT REGARDING FEDERALLY SPONSORED RESEARCH OR DEVELOPMENT

Not applicable.

### REFERENCE TO A “SEQUENCE LISTING”, A TABLE, OR COMPUTER PROGRAM

Not applicable.

### SUMMARY OF THE INVENTION

A novel floating gate (FG) transistor structure to safeguard the states of FG transistors against a reverse engineering skim, such as Scanning Capacitance Microscopy (SCM) is presented herein. The transistor substrate is implanted with an oppositely doped region. The addition of the doped substrate region does not alter the transistor normal operation characteristics significantly. In a preferred embodiment, the implantation occurs at the bottom of the substrate, close to the oxide interface and beyond the delayering limit. In various embodiments, the doped region is thicker than the non-doped region of the substrate. In one embodiment, the transistor is a Metal Oxide Semiconductor Field-Effect Transistor (MOSFET) with a floating gate (FG). In one embodiment, the substrate is a doped silicon substrate.

### DESCRIPTION OF THE DRAWINGS

The drawings constitute a part of this specification and include exemplary examples of the SECURED FLOATING GATE TRANSISTOR AND METHOD FOR SECURING FLOATING GATE TRANSISTORS, which may take the form of multiple embodiments. It is to be understood that in some instances, various aspects of the invention may be shown exaggerated or enlarged to facilitate an understanding of the invention. Therefore, drawings may not be to scale.

FIG. 1 provides a graph of the change in C-V Curves for a conventional FG MOS structure with P-type substrate.

FIG. 2 provides a rendering of the disclosed structure (MOPNS or MONPS) under SCM measurement.

FIG. 3(a) provides a rendering of the disclosed MOPNS structure under the influence of a small negative voltage applied to its gate.

FIG. 3(b) provides a rendering of the disclosed MONPS structure under the influence of a small negative voltage applied to its gate.

FIG. 4(a) depicts the upward band bending in energy band diagram while a small negative voltage is applied to the gate on a disclosed MOPNS structure.

FIG. 4(b) depicts the upward band bending in energy band diagram while a small negative voltage is applied to the gate on a disclosed MONPS structure.

FIG. 5 provides a graphical representation of charge density, electric field and electric potential of a MOPNS.

FIG. 6 provides a rendering of the donor concentration of a simulated MOPNS.

FIG. 7 shows a graphical comparison between the extracted model and simulation results (for HF and LF) of normalized C-V curves for the MOPNS.

FIG. 8 shows a graphical representation of the HF C-V curve of the MOPNS for a wider range on the X-axis.

FIG. 9 shows a comparison of the HF C-V curves of the FG MOPNS and FG MOS (P-type).

FIG. 10 shows a graphical comparison of HF C-V curve of the FG MOPNS with three different dopant concentrations for the N-type region while the dopant concentration is kept constant for the P-type region.

FIG. 11 shows the dopant concentration of a MOPNS transistor.

FIG. 12 shows a graphical comparison between I-V characteristics of FG MOPNS and FG MOS (P-type).

### FIELD OF THE INVENTION

The invention relates generally to integrated circuits and securing floating gate transistors.

### BACKGROUND OF THE INVENTION

Non-volatile memory has many applications, due to its ability to retain memory and programming after being power-cycled. One non-volatile memory mechanism is a Floating Gate Transistor (FGT). In an FGT, the transistor is a Metal Oxide Semiconductor Field-Effect Transistor (MOSFET) with a floating gate (FG) that can be charged by positive or negative charges to represent an “on” or “off” switch. The charge in the FG changes the threshold voltage of the FGT transistor. An array of FGTs can be used to construct an Electrically Erasable Programmable Read Only Memories (EEPROMs) or flash-EEPROM, which can be used in microcontrollers.

This type of memory is common in microprocessor/microcontroller designs, which gives the users the ability to program the integrated circuit (IC) chips. Additionally, the FGs help obfuscate the interconnections and functionality of the IC chip since some of the units are connected through programmed memory. In this case, the traditional non-destructive reverse engineering methods such as X-ray imaging are ineffective to extract the chip's functionality because the units are connected through the FGTs. However, there have been several attempts so recover stored data on the FGT, which raise a concern in the security of the IC chip design that is a key issue for electronic chip manufacturers.

Almost all successful reverse engineering methods are destructive and need backside preparation in order to recover the data from each FGT (i.e., to detect the charge on the FG, which distinguishes an on transistor from an off transistor). There are several successful methods for obtaining the presence of a charge on the FGs, including Scanning Kelvin Probe Microscopy (SKPM), Laser Timing Probe (LTP), and Scanning Capacitance Microscopy (SCM).

For SKPM, the entire silicon needs to be removed from the back of FGT, which has to be done in several steps to avoid damaging the oxide layer. The method measures the surface potential (i.e., electric field) and is considered to be ineffective for the smaller feature size device technologies (holding less than 1000 electrons on the FG). On the other hand, the LTP requires a layer of silicon left from the substrate, and this layer must be finely polished. To keep the silicon undamaged, the delayering should not exceed the limit of 50-200 nm. LTP measures the change in optical properties such as absorption coefficient, which is altered by a change in carriers density caused by a charged FG. This method also becomes inefficient for smaller feature designs since the variation in optical properties would be infinitesimal and requires equipment with much higher accuracy.

The SCM also needs to keep a layer of silicon beneath the oxide layer but does not require a fine polish on the remaining substrate. This method measures the capacitance seen between the control gate of the FG and the substrate versus the applied DC offset voltage. By varying the DC offset voltage, a C-V curve can be drawn. In the SCM setup, the control gate and substrate are connected to a high frequency small signal source with a variable DC offset voltage. Unlike SKPM and LTP, the SCM is even capable of detecting the charge on the FG for smaller feature size device technologies. This technique is believed to be effective as the feature size gets smaller.

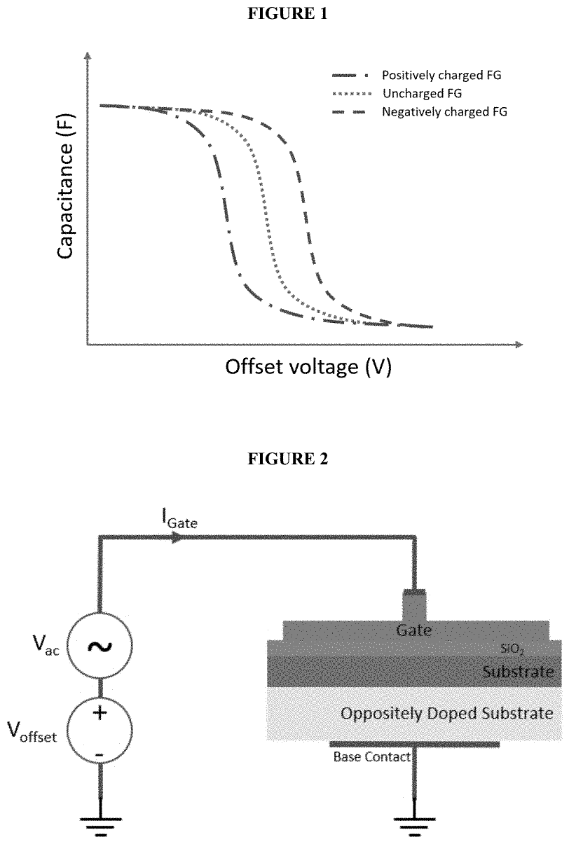

The C-V curves from a simple Metal Oxide Semiconductor (MOS) capacitor structure is like a MOSFET transistor without the implanted Drain and Source. The structure is considered to only have the oxide capacitance under accumulation mode and have the oxide capacitance in series with the depletion capacitance under depletion or inversion mode in high frequency capacitance measurements. This could be extended to an FG MOS structure that follows the same trend in C-V curves. Depending on the substrate dopant (N-type and P-type) and also the type of charge (positive or negative) placed on the FG, these curves would either shift to the right or left when the FG is charged. An example for an FG MOS structure with a P-type substrate is shown in FIG. 1. One can choose a certain point on the offset voltage axis of this C-V curve that shows a lower capacitance from a positively charged FG than an uncharged or a negatively charged FG, which can distinguish the positively charged FGs from uncharged FGs, which—through SCM—exposes the FGT transistor states.

### DETAILED DESCRIPTION OF THE INVENTION

Herein disclosed is a novel design structure for FG transistors, which safeguards the FG transistors against vigorous reverse engineering skim (SCM). In this design, an oppositely doped region is implanted at the bottom of the silicon substrate, close to the oxide interface beyond the delayering limit without changing the transistor's normal operating characteristics.

To validate this design, a model was extracted to describe the new design's C-V characteristic. This was then validated by the simulation results from the COMSOL. Later an FG MOPNS was compared to its traditional FG MOS that showed a significant drop in the maximum measured value in capacitance as well as a huge drop in the difference between maximum and minimum measured capacitance. Furthermore, the results shown to have the same trend as a P-type FG MOS when the dopant concentration of the implanted layer is very low compared to the substrate. On the other hand, the behavior observed to be the same as a N-type FG MOS when the dopant concentration of the implanted layer is very high compared to the substrate. Finally, the I-V characteristic of an FG MOPNS transistor were compared to a P-type FG MOS transistor and very little difference in the behavior were observed, which means the proposed structure has the similar functionality of a traditional FG MOS transistor.

In the disclosed structure, an oppositely doped compensated silicon region is formed by ion implanting of opposite dopant in the extrinsic substrate a distance away from the SiO₂—Si interface so that after back-side delayering, the structure ends up with at least slightly thicker oppositely doped region than the remaining substrate thickness depicted in FIG. 2. Hereinafter, the structure with the P-type substrate will be referred to as the “Metal Oxide P-type N-type Semiconductor” (MOPNS) and structure with the N-type substrate will be the “Metal Oxide N-type P-type Semiconductor” (MONPS).

As seen in FIG. 2, the thickness of the “oppositely doped substrate” is at least slightly greater than the thickness of the extrinsic “substrate” after delayering from the bottom. Both regions also have the same effective opposite dopant concentrations. This means that if the substrate is doped with acceptor/donor atoms, the bottom side of the substrate would be compensated with oppositely donor/acceptor atoms so that the majority carriers of each section can be approximately the same. Considering these two characteristics at thermal equilibrium, if the substrate region depth is small enough (in tens of nm) almost all majority carriers got diffused to the oppositely doped region and leave their positive or negative ions behind. That is, the holes are being diffused to meet the electrons for annihilation and vice versa. This would happen until there are not many majority carriers left on the top of the substrate slabs (i.e., the region is depleted from majority carriers).

Relatively, the oppositely doped region is depleted for a certain depth, which would be equal to the depths of the substrate region when no voltage is applied to its gate at thermal equilibrium. Therefore, the capacitance can be found by treating the structure as two parallel plates capacitors. Similar to the MOS, this structure has a constant oxide capacitance in series with the capacitance from the depleted silicon (Ca) below the oxide layer. The Ca is inversely proportional to the depleted silicon depth.

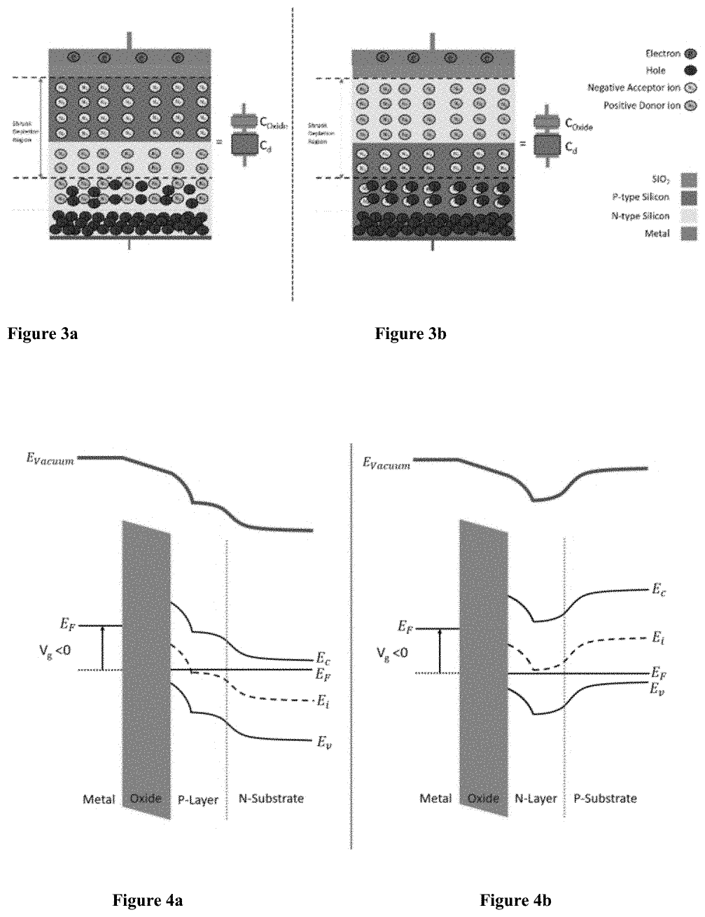

Stated alternatively, in the capacitance measurement the bottom of the device is connected to the ground, which can be considered an abundant source of holes or electrons. However, these holes or electrons cannot invade the depletion region since the positive or negative ions repel them, but by adding small negative or positive potential on the gate (i.e., creating an electric field) some of these holes or electrons eventually push through the depletion region to make it tighter. It is important to note that the process of shrinking the depletion region in a MONPS would be easier (i.e., the depletion region depth would get smaller) when a small negative voltage is applied to the gate than a small positive potential. This comes from the fact that, in the case of applying a small negative voltage to a MONPS, the holes are trying to push through the depleted P-type region with negative ions since the created electric field from the gate is upward, which is easier than penetrating a depleted P-type region (full of negative ions) with electrons when a positive voltage is applied to the gate. A similar condition can be applied to a MOPNS but with the opposite voltage polarities applied to the gate. A graphical representation of this process for a small negative potential applied to the gate of both MOPNS and MONPS can be seen in FIG. 3.

In a high frequency case, by increasing the applied potential to the gate, this depletion depth approaches a minimum value, which causes the capacitance to go up to a certain point. Since there is not enough time for the thermal generation of electrons or holes, the depletion region stands still. However, in the low frequency case, the depleted region vanishes and we will only be left by the oxide capacitance.

From an energy band diagram review, there will be an imposed potential over the oxide and the semiconductor when a voltage is applied to the gate. The applied potential to the semiconductor would cause band bending (upward or downward depending on the polarities of the applied voltage) close to the oxide interface. For example, an upward band bending can be seen in FIGS. 4(a) and 4(b) when a negative potential is applied to the gate of an MOPNS (FIG. 4(a)) and an MONPS (FIG. 4(b)). This band bending would continue until the surface is inverted as much as the oppositely doped substrate, which has the same dopant concentration as the substrate.

To model the capacitance, the depth of the depleted region must be found. For exemplary purposes, the MOPNS capacitance is to be determined. To reach this goal, the electric field is first found. The boundary condition here assumes the electric field to be zero outside of the N-type depleted region (E(x>x_{d})=0).

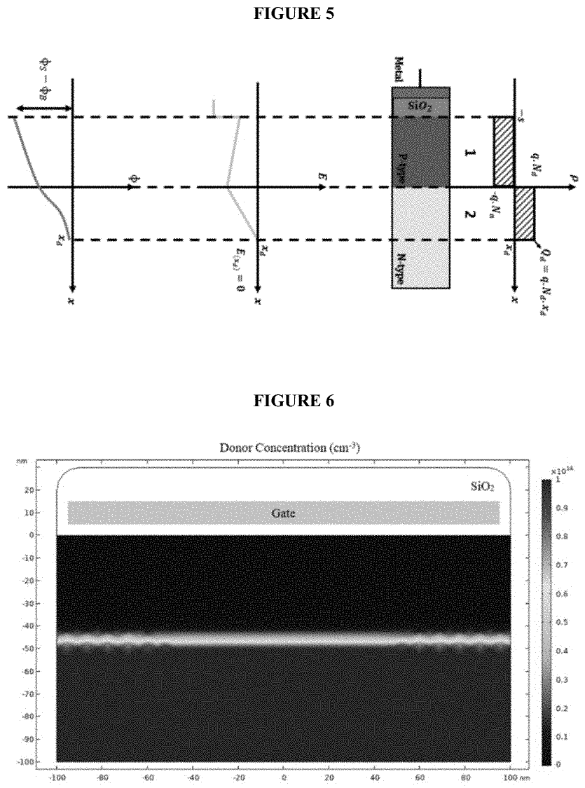

By looking at FIG. 5, one could find the electric fields in both P-type (E₁) and N-type (E₂) regions by integrating the charge density divided by the permittivity over each region (from Gauss's law). The electric filed in each region can be found using the following:

$$\begin{matrix}{E}_{1} ( x ) = \frac{- q}{{ɛ}_{s}} ( {x}_{d} \cdot {N}_{d} + {N}_{a} \cdot x ) & ( 1 ) \\ {E}_{2} ( x ) = \frac{- q \cdot {N}_{d}}{{ɛ}_{s}} ( - x + {x}_{d} ) & ( 2 )\end{matrix}$$

Where q is the elementary charge, εₛ is the permittivity of the silicon, Nₐ and N_{d} are the acceptor and donor concentrations of the P-type and N-type regions respectively and x_{d} is the depth of the depleted N-type region.

By having the electric field, one can calculate the electric potential over the semiconductor by integrating the electric field (with a negative sign) over both regions. So, the potential drop over the semiconductor can be calculated as:

$${Φ}_{s} = \frac{q}{2 {ɛ}_{s}} [ {N}_{a} \cdot {S}^{2} - 2 {N}_{d} \cdot {x}_{d} \cdot S - {N}_{d} \cdot {x}_{d}^{2} ] + {Φ}_{B} \qquad ( 3 )$$

Where S is the depth of the P-type region that is considered to be depleted and the ϕ_{B} is known as the built-in potential which is:

$${Φ}_{B} = \frac{k T}{q} ln \frac{{N}_{a} \cdot {N}_{d}}{{n}_{i}^{2}} \qquad ( 4 )$$

Where k is the Boltzmann constant, T is temperature in Kelvin and nᵢ is the intrinsic carrier concentration.

The applied voltage to the gate (V_{Gate}) is the sum of the potential on the oxide (V_{oxide}), flat band voltage (V_{fb}) and the potential drop over the semiconductor.

V_{Gate}=V_{oxide}+V_{fb}+ϕₛ (5)

One can easily obtain the V_{oxide} by finding the electric field at the oxide interface and applying the fact that electric displacement must be continuous at the silicon and oxide interface. So, the above equation can be simplified to:

$${V}_{Gate} = \frac{q}{{C}_{o x}} [ {N}_{a} \cdot S - {N}_{d} \cdot {x}_{d} ] + {V}_{f b} + {Φ}_{s} \qquad ( 6 )$$

The x_{d} can be calculated using Equations 3 and 6 with respect to the applied gate voltage. So, the capacitance of the depleted semiconductor can be found as:

$${C}_{d} = \frac{{ɛ}_{s}}{( {x}_{d} + S )} \qquad ( 7 )$$

The total capacitance would be the constant oxide capacitance in series with C_{d}.

To validate the given formula, a 2D COMSOL simulation has been done on a MOPNS with the same dimensions as that shown in FIG. 6 to find the low and high frequency capacitance of the device versus the offset voltage applied to the gate. As can be seen in FIG. 6, the bottom N-type revision has the donor concentration of N_{d}=10¹⁶ [cm⁻³] that is considered to be equal to the acceptor concertation (not shown) on the top P-type region. Finally, the amplitude of the small signal considered to be infinitesimal with respect to the change in the applied offset (V_{ac}=100 μV) when the bottom of the structure is grounded (V_{Base}=0V).

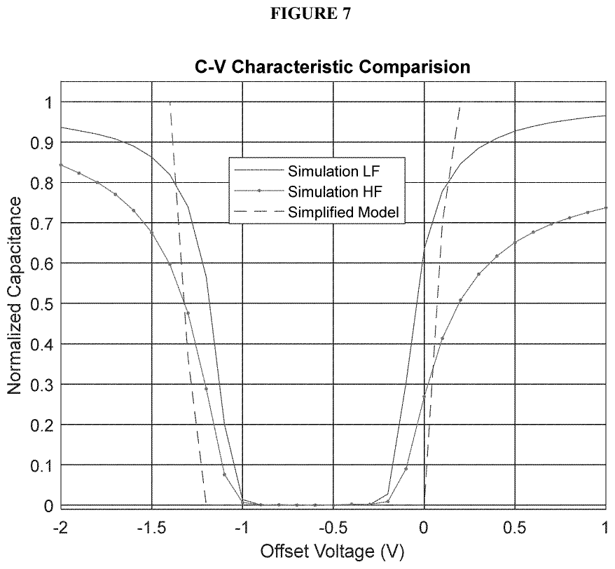

By the use of Equations 3, 6, and 7, the C-V behavior of the device is drawn and compared to the simulation in FIG. 7. This demonstrates that our extracted model follows the similar pattern as the simulation, so the model could be used to describe the C-V characteristics of the proposed structure. However, the simulation provides greater details and also can take the effect of applied high frequency into account, which was not implemented in the simple model.

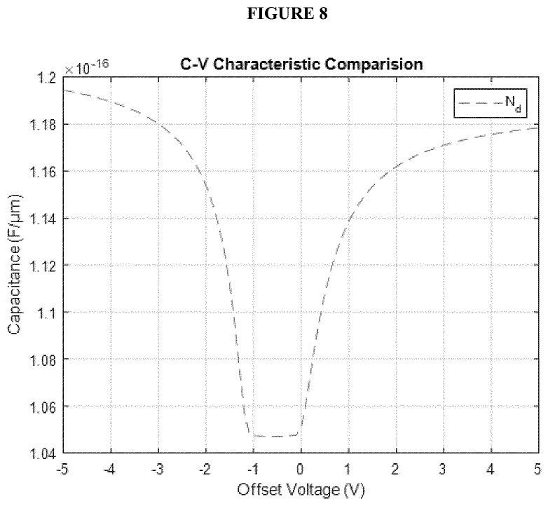

Since SCM only uses high frequency capacitance measurements, the high frequency C-V curves is favorable. In FIG. 8, the simulated high frequency C-V characteristic of the mentioned MOPNS is sketched for a wider range of applied offset voltage. As expected, the capacitance is slightly lower when a relatively strong positive voltage is applied to the gate than when a relatively strong negative voltage is applied.

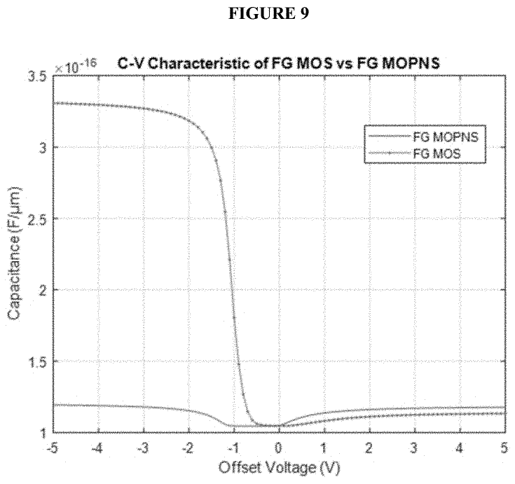

As an additional test, the FG MOPNS is compared with a traditional FG MOS. A realistic structure of a P-type FG MOS with a donor concentration of N_{d}=10¹⁶[cm⁻³] at the substrate is simulated. The same structure size is used for the FG MOPNS device when its bottom half is doped to be an N-type silicon with the same acceptor concentration as the donor concentration Nₐ=N_{d}=10¹⁶ [cm⁻³] on top similar to FIG. 6. A comparison between the high frequency C-V curves of the P-type FG MOS and FG MOPNS when there is no charge is placed on the FG is shown in FIG. 9. From this, there is a significant change in the C-V behavior as well as a significant drop (64%) in the maximum obtained capacitance and an even more substantial drop (1600%) in the difference between the minimum and maximum measured capacitance compared to an FG MOS is observed.

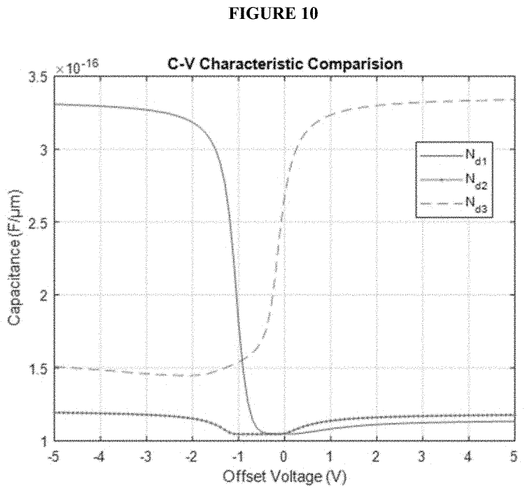

It may also be of interest to compare the C-V curves of the disclosed device when the oppositely doped substrate is lightly or highly doped with respect to the substrate. So, another simulation has been done on the previously described FG MOPNS structure, but on three different donor concentrations at the oppositely doped substrate (N-type region) while the substrate (P-type region) is kept constant at Nₐ=10¹⁶ [cm⁻³]. FIG. 10 shows this comparison between the three different donor concentrations of N_{d1}=10¹⁴ [cm⁻³], N_{d2}=10¹⁶ [cm⁻³], and N_{d3}=5×10¹⁷ [cm⁻³] for N-type region. As seen in FIG. 10, the structure can be treated as a simple P-type FG MOS when the dopant concentration of the N-type region is significantly smaller than the P-type region. The opposite can be seen when the dopant concentration of the N-type region is significantly higher than the P-type region, and thus can be treated as an N-type FG MOS. Both obtained results from equal and greater dopant concentration of the oppositely doped region are desirable since they both indicate a significant change in the C-V characteristic of the device in comparison to the traditional P-type FG MOS. So, it can be said that the change in dopant concentration adds a security feature to this device. In other words, choosing the right device with the right C-V curve can become challenging.

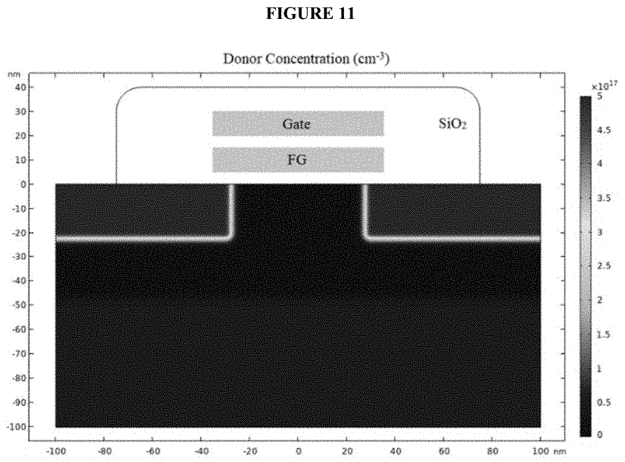

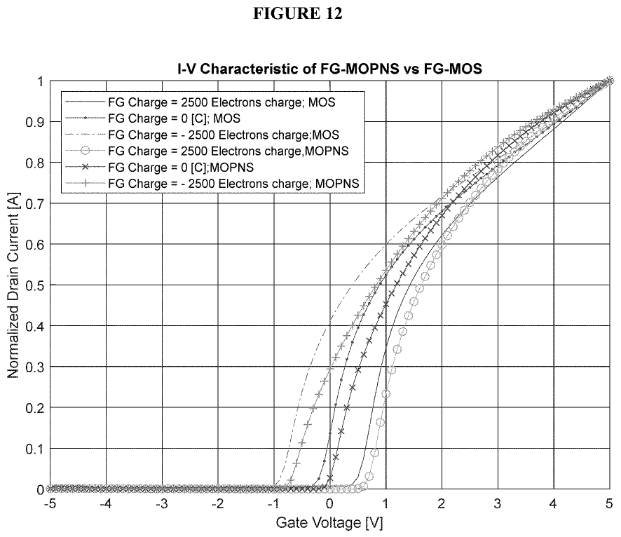

To have a properly functioning device, it must have similar functionality (i.e., I-V characteristic) as a simple FG MOS. To confirm the design, a simulation was performed on an FG MOPNS transistor with the same structure size as FIG. 11. This figure shows the donor concentration of the device when both the substrate and the oppositely doped substrate have the same dopant concentration as N_{d}=Nₐ=5×10¹⁶[cm⁻³] and the heavily doped regions, which are the drain and source, have the donor concentration of N_{d}=5×10¹⁷ [cm⁻³]. The drain is held at 100 μV while the source and the base are grounded. FIG. 12 shows a comparison between the normalized I-V characteristic of the mentioned designed FG MOPNS and a traditional P-type FG MOS with the same size and dopant concentration.

As seen from FIG. 12, the I-V characteristic has not changed significantly. The desirable shifts in the I-V characteristic can clearly be observed when the FG is positively or negatively charged. This represent that the new design follows a similar trend in I-V characteristic as an FG MOS counterpart.

While the disclosed system and method was designed for use with integrated circuits that are at risk for being reverse-engineered using SCM, the features and advantages of this design described in the application can be utilized by a number of different applications, technologies, and industries.

The described features, advantages, and characteristics may be combined in any suitable manner in one or more embodiments. One skilled in the relevant art will recognize that the various components of this design may be practiced without one or more of the specific features or advantages of a particular embodiment. In other instances, additional features and advantages may be recognized in certain embodiments that may not be present in all embodiments.

Reference throughout this specification to “one embodiment”, “an embodiment”, or similar language means that a particular feature, structure, or characteristic described in connection with the embodiment is included in at least one embodiment. Thus, the appearance of the phrase “in one embodiment”, “in an embodiment”, and similar language throughout this specification may, but do not necessarily, all refer to the same embodiment.

Reference throughout this specification to “programming” or “functionality” provided for the invention refers to software or hardware implementation of this functionality, methods for performing which are known in the art.

1. A metal oxide semiconductor transistor comprising:
a. a gate;
b. a silicon dioxide interface; and
c. a silicon substrate comprising an oxide interface;
wherein said silicon substrate comprises an extrinsic portion and a doped portion;
wherein said doped portion is implanted with an oppositely doped region;
wherein said oppositely doped region is located at the bottom of said silicon substrate and a distance away from said oxide interface; and
said extrinsic portion is located at the top of said silicon substrate.

2. The transistor of claim 1 wherein said distance away from said oxide interface is a distance such that after back-side delayering, said doped portion is thicker than said extrinsic portion.

3. The transistor of claim 1 wherein said doped portion and said extrinsic portion each comprise the same or greater effective opposite dopant concentrations.

4. The transistor of claim 1 wherein said silicon substrate is a P-type substrate.

5. The transistor of claim 1 wherein said silicon substrate is a N-type substrate.

6. A method for securing a floating gate transistor comprising:
a. identifying the floating gate transistor to be secured, wherein said floating gate transistor comprises a silicon dioxide—silicon interface and a substrate, and wherein said substrate comprises an extrinsic portion and a doped portion; and
b. implanting oppositely doped ions in the extrinsic portion.
